(19) United States
(12) Patent Application Publication
(10) Pub. No.: US 2001/0048120 A1
(43) Pub. Date: Dec. 6, 2001

(54) Heterojunction bipolar transistor composed of emitter layer which includes orderly structured layer and disorderly structured layer

(75) Inventor: Hidenori Shimawaki, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/871,652

(22) Filed: Jun. 4, 2001

(30) Foreign Application Priority Data
Jun. 2, 2000 (JP) 166188/2000

(51) Int. Cl. H01L 31/0328

(52) U.S. Cl. 257/198

(57) ABSTRACT

A heterojunction bipolar transistor is composed of a substrate, a collector layer covering the substrate, a base layer formed on the collector layer, an emitter layer formed on the base layer, and an emitter contacting semiconductor layer formed on the emitter layer. The base layer is doped with a first conductive type dopant. The emitter layer is formed of a mixed crystal of first and second compound semiconductors, and doped with a second conductive type dopant. The emitter contacting semiconductor layer is doped with the second conductive type dopant. The emitter layer includes a superlattice layer connected to the base layer, and a disordered layer connected to the emitter contacting semiconductor layer. The first and second compound semiconductors are layered to form a superlattice in the superlattice layer, and the first and second compound semiconductors are irregularly layered in the disordered layer.

### BACKGROUND OF THE INVENTION

1. Field of the Invention

The present invention relates to a heterojunction bipolar transistor and an integrated including the same. More particularly, the present invention relates to a heterojunction bipolar transistor composed of emitter layer including disordered layer, and an integrated circuit including the same.

2. Description of the Related Art

A heterojunction bipolar transistor (HBT) has several advantages over a homojunction bipolar transistor and a field effect transistor (FET), such as superior current drive ability and excellent high frequency property. An emitter injection efficiency of the HBT is not decreased by a high dopant concentration in the base region, which realizes the excellent high frequency property of the HBT. Also, carriers are transported vertically in the HBT, therefore a transit property of the carriers is mainly determined by a structure of a crystal layer. This enables to improve the high frequency property of the HBT without a fine photolithography technique.

In recent years, the research and development of an InGaP/GaAs HBT using an InGaP/GaAs heterojunction have been vigorously done. The InGaP/GaAs HBT has the following advantages. First, the InGaP is lattice-matched with GaAs substrate when a composition of indium is close to 0.5. Second, a valence band discontinuity formed on the InGaP/GaAs junction is large, while a conduction band discontinuity is small. Third, selective etching of InGaP and GaAs is easy. Fourth, a deep donor impurity level is not present, while Al containing compound semiconductor includes deep donor impurity levels such as a DX center. Finally, recombination rates on a surface and a boundary are small.

It is known that the micro crystal structure of an InGaP film is varied depending on crystal growth conditions. An InGaP crystal is a mixed crystal of InP and GaP. In the InGaP crystal, phosphorus layers and Group III element layers are alternately layered. Here, the Group III element layer means a layer consisting of indium and/or gallium. In some crystal growth conditions, indium layers and gallium layers are regularly layered, and an InGaP film having a superlattice structure is obtained. In such an InGaP film, indium phosphide and gallium phosphide are regularly layered to form the superlattice structure. The superlattice structure may be referred to as an ordered structure, hereinafter. In other crystal growth conditions, indium and gallium are irregularly arrayed so that a disordered structure is formed. A band gap width of the InGaP is generally changed in a range between 1.83 and 1.93 eV depending on the micro crystal structure of the InGaP film. This change is mainly reflected in the conduction band discontinuity on the InGaP/GaAs heterojunction. The usage of the InGaP having the ordered structure reduces the conduction band discontinuity on the InGaP/GaAs heterojunction boundary, and thereby reduces an offset voltage in a collector current and voltage property of the HBT. The reduction of the offset voltage enables a power amplifier using the HBT to show an excellent efficiency at a low voltage operation.

However, the formation of a GaAs layer on an InGaP layer having the ordered structure increases a resistance between the GaAs layer and the InGaP layer. The gallium atoms in the GaAs layer are not positioned at appropriate lattice points near the boundary between the InGaP and GaAs layers, which induces traps on the boundary. The traps increase the boundary resistance.

For the reduction of the boundary resistance, an HBT including an InGaP layer having the disordered structure is disclosed in Japanese Laid Open Patent Application (JP-A-Heisei 11-243058). The conventional HBT is composed of a half-insulating GaAs substrate 101, as shown in FIG. 1. An i-GaAs layer 102, a sub-collector layer 103 made of n-GaAs, a collector layer 104 made of n-GaAs, a base layer 105 made of p-GaAs, an emitter layer 106 made of n-InGaP, an n-GaAs layer 107 and an n-InGaAs layer 108 are sequentially laminated on the GaAs substrate 101. An emitter cap layer 109 is constituted by the n-GaAs 107 and the n-InGaAs layer 108. A collector electrode 110 is formed on the sub-collector layer 103, a base electrode 111 is formed on the base layer 105, and an emitter electrode 112 is formed on the n-InGaAs layer 108. The emitter layer 106 is formed by the InGaP layer having the disordered structure. Such disordered structure preventing traps from being generated, and thereby reduces the resistance between the emitter layer 106 and the emitter cap layer 109.

In the case of the HBT using the InGaP/GaAs heterojunction, a current gain in a low current region depends on the crystal structure of the InGaP layer. That is, when the InGaP layer having the disordered structure is used in the emitter, a high current gain is obtained even in a low collector current region. On the contrary, when the InGaP layer having the order array structure is used in the emitter, a base leak current is increased in the low collector current region. The property of the drop in the current gain is remarkably induced.

FIGS. 2 and 3 explains such property. FIG. 2 shows an energy band diagram of an emitter/base junction when the InGaP layer having the ordered structure is used in an emitter layer. In FIG. 8, A region 4d corresponds to a base layer of p-GaAs. A region 5d corresponds to the emitter layer of n-InGaP having the ordered structure. A region 7d corresponds to an n-GaAs layer of a relatively low dopant concentration, and a region 8d corresponds to an n-GaAs layer of a high dopant concentration, the both n-GaAs layers constituting an emitter contacting layer. As mentioned above, the usage of the InGaP layer having the ordered structure suppresses the conduction band disconnection between the emitter layer and the base layer. Thus, the energy barrier to electrons injected to the base from the emitter is small to a degree that it is not actually trouble.

However, the usage of the InGaP layer having the ordered structure also reduces an effective energy barrier EV2 for holes in the base layer. This partly arises from the reduction in the band gap width of the InGaP layer. In addition, traps are induced in the boundary between the emitter layer (corresponding to the region 5d) and the emitter contacting layer (corresponding to the region 7d), which eliminates carries near the boundary. The reduction in the band gap width and the elimination of the carriers drop the effective energy barrier EV2.

The reduction of the effective energy barrier EV2 leads to the increase in the base leak current. An experiment by the inventor proves that the increase in the base leak current is enormous when a thickness of the emitter layer is 150 nm or less. The experiment also proves that the base leak current is remarkably increased when the n-type impurity concentration near boundary between the n-InGaP layer and the n-GaAs layer is less than 10¹⁸ cm⁻³.

The increase in the base leak current reduces the current gain especially in the low collector current region.

Also, the increase in the base leak current enhances the recombination in the base layer, which degrades the reliability of the HBT.

FIG. 3 shows an energy band diagram of an emitter/base junction when the InGaP layer having the disordered structure is used in an emitter layer. A region 4e corresponds to a base layer of p-GaAs. A region 6e corresponds to the emitter layer of n-InGaP having the disordered structure. A region 7e corresponds to an n-GaAs layer of a relatively low dopant concentration and a region 8e corresponds to an n-GaAs layer of a high dopant concentration, both the n-GaAs layers constituting an emitter contacting layer. The disordered structure in the emitter layer suppresses the occurrence of traps in the boundary between the emitter layer (corresponding to region 6e) and the emitter contacting layer (corresponding to the region 7e). Thus, an effective energy barrier EV3 for holes in the base layer is kept relatively high, which reduces the base leak current.

However, the usage of the disordered structure in the emitter layer causes the increase in the conduction band discontinuity on the InGaP/GaAs heterojunction, which results in the generation of the energy barrier for electrons on the emitter/base junction boundary. The conventional HBT suffers from a large offset voltage appearing in the collector current voltage property.

Other techniques concerning heterojunction bipolar transistors and high electron mobility transistors (HEMT) are disclosed in Japanese Laid Open Patent Application (JP-A-Heisei 6-168960, 7-106343, 8-107117, 8-293505, and 10-144699). The other techniques, however, are not related to the ordered structure and disordered structure.

Desirably, the offset voltage appearing in the collector current voltage property is reduced in the HBT.

It is also desirably to reduce the base leak current of the HBT.

Furthermore, it is desired to improve the current gain of the HBT.

It is also desirably to improve the reliability of the HBT.

### SUMMARY OF THE INVENTION

Therefore, an object of the present invention is to reduce an offset voltage appearing in the collector current voltage property of an HBT.

Another object of the present invention is to reduce a base leak current of an HBT.

Still another object of the present invention is to improve the current gain of an HBT.

Yet still another object of the present invention is to improve the reliability of an HBT.

In order to achieve an aspect of the present invention, a heterojunction bipolar transistor is composed of a substrate, a collector layer covering the substrate, a base layer formed on the collector layer, an emitter layer formed on the base layer, and an emitter contacting semiconductor layer formed on the emitter layer. The base layer is doped with a first conductive type dopant. The emitter layer is formed of a mixed crystal of first and second compound semiconductors, and doped with a second conductive type dopant. The emitter contacting semiconductor layer is doped with the second conductive type dopant. The emitter layer includes a superlattice layer connected to the base layer, and a disordered layer connected to the emitter contacting semiconductor layer. The first and second compound semiconductors are layered to form a superlattice in the superlattice layer, and the first and second compound semiconductors are irregularly layered in the disordered layer.

Desirably, the first conductive type dopant is a P-type dopant and the second conductive type dopant is an N-type dopant.

It is desirable that the first compound semiconductor is desirably indium phosphide and the second compound semiconductor is desirably gallium phosphide.

The base layer is desirably formed of gallium arsenide.

The mixed crystal desirably has a chemical formula of InₓGa₍₁₋ₓ₎P, where 0.47≦×≦0.52.

The emitter contacting semiconductor layer is desirably formed of gallium arsenide.

A thickness of the emitter layer is desirably 50 nm or less.

The emitter layer has a first width in a first direction parallel to a surface of the substrate, and the emitter contacting semiconductor layer has a second width in the first direction. In this case, the first width is desirably larger than the second width.

The disordered layer may be composed of a first portion connected to the superlattice layer, and a second portion protruding from the first portion in a second direction orthogonal to a surface of the substrate. The second portion and the emitter contacting semiconductor layer constitute an emitter mesa. The first portion and the superlattice layer have a third width in a first direction parallel to the surface, and the emitter mesa has a fourth width in the first direction. The third width is desirably larger than the fourth width.

In this case, a sum of thicknesses of the first portion and the superlattice layer is desirably 50 nm or less.

The emitter layer may further include an intermediate layer formed between the superlattice layer and the disordered layer. In this case, the first and second compound semiconductors are less irregularly layered in the intermediate layer than in the disordered layer.

In order to achieve another aspect of the present invention, an integrated circuit is composed of a heterojunction bipolar transistor. The heterojunction bipolar transistor is composed of a substrate, a collector layer covering the substrate, a base layer formed on the collector layer, an emitter layer formed on the base layer, and an emitter contacting semiconductor layer formed on the emitter layer. The base layer is doped with a first conductive type dopant. The emitter layer is formed of a mixed crystal of first and second compound semiconductors, and doped with a second conductive type dopant. The emitter contacting semiconductor layer is doped with the second conductive type dopant. The emitter layer includes a superlattice layer connected to the base layer, and a disordered layer connected to the emitter contacting semiconductor layer. The first and second compound semiconductors are layered to form a superlattice in the superlattice layer, and the first and second compound semiconductors are irregularly layered in the disordered layer.

In order to achieve still another aspect of the present invention, an amplifier amplifying a signal having a microwave frequency is composed of a heterojunction bipolar transistor. The heterojunction bipolar transistor is composed of a substrate, a collector layer covering the substrate, a base layer formed on the collector layer, an emitter layer formed on the base layer, and an emitter contacting semiconductor layer formed on the emitter layer. The base layer is doped with a first conductive type dopant. The emitter layer is formed of a mixed crystal of first and second compound semiconductors, and doped with a second conductive type dopant. The emitter contacting semiconductor layer is doped with the second conductive type dopant. The emitter layer includes a superlattice layer connected to the base layer, and a disordered layer connected to the emitter contacting semiconductor layer. The first and second compound semiconductors are layered to form a superlattice in the superlattice layer, and the first and second compound semiconductors are irregularly layered in the disordered layer.

In order to achieve yet still another aspect of the present invention, an oscillator generating an oscillating signal having an EHF (Extremely High Frequency) is composed of a heterojunction bipolar transistor. The heterojunction bipolar transistor includes a substrate, a collector layer covering the substrate, a base layer formed on the collector layer, an emitter layer formed on the base layer, and an emitter contacting semiconductor layer formed on the emitter layer. The base layer is doped with a first conductive type dopant. The emitter layer is formed of a mixed crystal of first and second compound semiconductors, and doped with a second conductive type dopant. The emitter contacting semiconductor layer is doped with the second conductive type dopant. The emitter layer includes a superlattice layer connected to the base layer, and a disordered layer connected to the emitter contacting semiconductor layer. The first and second compound semiconductors are layered to form a superlattice in the superlattice layer, and the first and second compound semiconductors are irregularly layered in the disordered layer.

### BRIEF DESCRIPTION OF THE DRAWINGS

FIG. 1 is a section view showing a known semiconductor device;

FIG. 2 is a diagram showing a known energy band of an emitter/base junction;

FIG. 3 is a diagram showing another known energy band of the emitter/base junction;

FIG. 4 is a section view showing an embodiment of a semiconductor device according to the present invention;

FIG. 5 is a diagram showing an energy band in the above-mentioned embodiment;

FIG. 6 is a section view showing another embodiment of the semiconductor device according to the present invention;

FIG. 7 is a section view showing still another embodiment of the semiconductor device according to the present invention;

FIG. 8 is a circuit diagram showing an embodiment of a semiconductor integrated circuit according to the present invention; and

FIG. 9 is a circuit diagram showing another embodiment of the semiconductor integrated circuit according to the present invention.

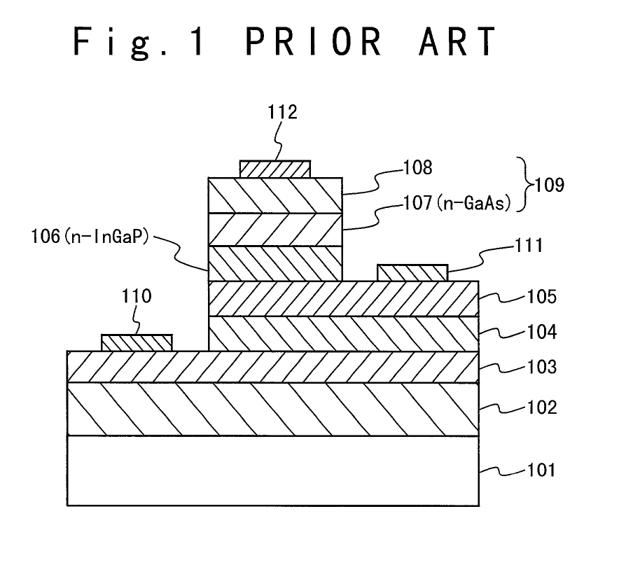

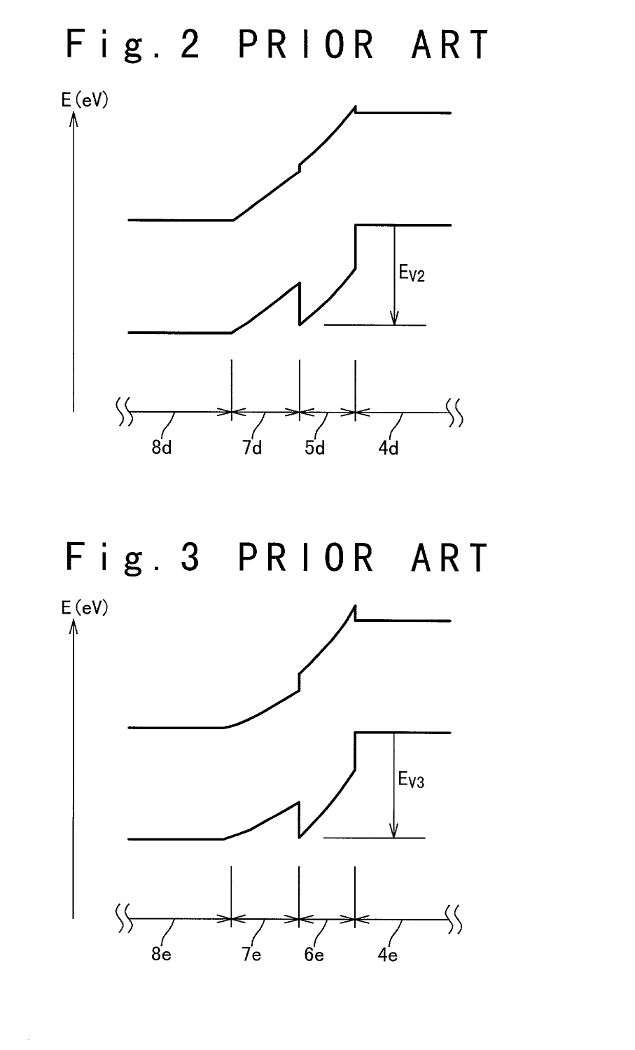

### DESCRIPTION OF THE PREFERRED EMBODIMENTS

A heterojunction bipolar transistor (HBT) of the present invention will be described below in detail with reference to the accompanying drawings.

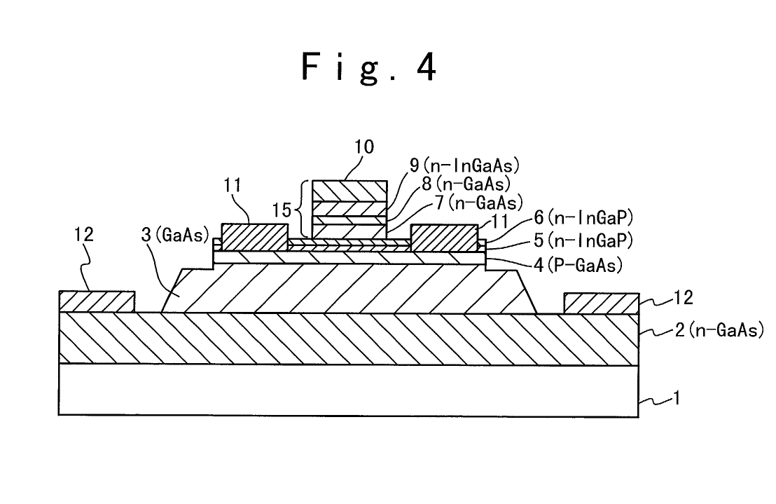

FIG. 4 shows a structure of an embodiment of the HBT of the present invention. An n-GaAs layer 2 is formed on a half-insulating GaAs substrate 1. The n-GaAs layer 2 functions as a collector contact layer. The n-GaAs layer 2 has a film thickness of 500 nm and a dopant concentration of 3×10¹⁸ cm⁻³.

An undoped GaAs layer 3 having a film thickness of 700 nm is formed on an upper surface of the n-GaAs layer 2. The GaAs layer 3 functions as a collector layer. The GaAs layer 3 may be formed of n-GaAs instead of undoped GaAs.

A p-GaAs layer 4 is formed on an upper surface of the undoped GaAs layer 3. The p-GaAs layer functions as a base layer. The p-GaAs layer 4 has a film thickness of 100 nm and a dopant concentration of 4×10¹⁹ cm ⁻³.

An n-InGaP layer 5 having an ordered structure is formed on an upper surface of the p-GaAs layer 4. The n-InGaP layer 5 is formed of a mixed crystal of indium phosphide and gallium phosphide, and the indium phosphide and gallium phosphide are regularly layered to form a superlattice structure in the n-InGaP layer 5. The n-InGaP layer has a film thickness of 25 nm and a dopant concentration of 3×10¹⁷ cm⁻³.

An n-InGaP layer 6 having a disordered structure is formed on an upper surface of the n-nGaP layer 5. In the n-InGaP layer 6, indium phosphide and gallium phosphide are irregularly layered. The n-InGaP layer 6 has a film thickness of 15 nm and a dopant concentration of 3×10¹⁷ cm⁻³. The n-InGaP layer 5 and the n-InGaP layer 6 functions as an emitter layer.

An n-GaAs layer 7 is formed on an upper surface of the n-InGaP layer 6. The n-GaAs layer 7 has a film thickness of 100 nm and a dopant concentration of 3×10¹⁷ cm⁻³.

An n-GaAs layer 8 is formed on an upper surface of the n-GaAs layer 7. The n-GaAs layer 9 has a film thickness of 50 nm and a carrier concentration of 3×10¹⁸ cm⁻³. The n-GaAs layer 7 and the n-GaAs layer 8 constitute an emitter contact layer.

An n-InGaAs layer 9 is formed on an upper surface of the n-GaAs layer 8. The n-InGaAs layer has a film thickness of 100 nm and a carrier concentration of 2×10¹⁹ cm⁻³. The n-InGaAs layer 9 constitutes an emitter cap layer.

The above-mentioned structure is formed by a metal organic chemical vapor deposition. While the p-InGaP layer 5 and the n-InGaP layer 6 are formed, the crystal growth temperatures are changed to thereby change the regularity of the p-InGaP layer 5 and the n-InGaP layer 6.

An emitter electrode 10 is formed on an upper surface of the n-InGaAs layer 9. An ohmic contact is achieved between the n-InGaAs layer 9 and the emitter electrode 10. The n-GaAs layer 7, the n-GaAs layer 8, the n-InGaAs layer 9 and the emitter electrode 10 constitute an emitter mesa 15.

Base electrodes 11 are formed on the p-GaAs layer 4 to penetrate the n-InGaP layer 5 and the n-InGaP layer 6. The base electrodes 11 are electrically connected to the base layer 4. The surface of the base layer 4 is not exposed, that is, completely covered by the n-InGaP layer 5 and the base electrodes 11.

Collector electrodes 12 are formed on an upper surface of the n-GaAs layer 2.

A width of the emitter mesa 15 is smaller than that of the emitter layer constituted by the n-InGaP layer 5 and 6 in the direction parallel to the surface of the GaAs substrate 1. A part of the n-InGaP layer 6 is not covered by the emitter mesa 15. That is, the part of the n-InGaP layer 6 is exposed.

An exposed portion of the emitter layer that is not covered by the emitter mesa 15 is completely depleted, because of its thin thickness of 40 nm. The thickness of 40 nm is sufficiently small to deplete the exposed portion. The exposed portion functions as a surface protection layer for the p-GaAs layer 4. To completely deplete the exposed portion, the thickness of the emitter layer is desirably 50 nm or less.

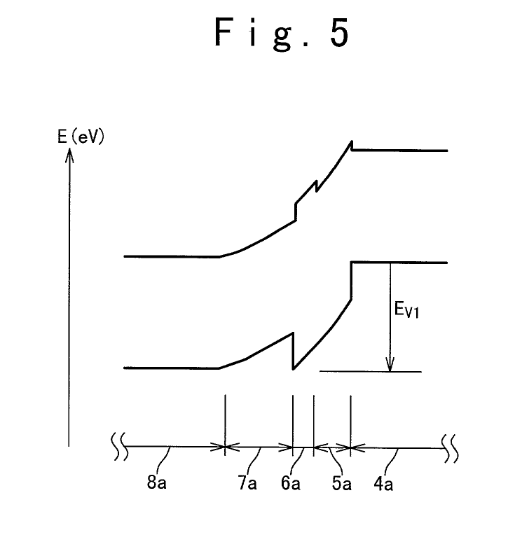

FIG. 5 shows an energy band diagram of the HBT shown in FIG. 4. A portion 4a represents the p-GaAs layer 4. A portion 5a represents the n-InGaP layer 5, which has the ordered structure. A portion 6a represents the n-InGaP layer 6, which has the disordered structure. A portion 7a represents the n-GaAs layer 7. And, a portion 8a represents the n-GaAs layer 8.

As shown in FIG. 5, the ordered structure of the n-InGaP layer 5 reduces the conduction band discontinuity in the junction of the p-GaAs layer 4 and the n-InGaP layers 5, that is, the emitter/base junction.

Also, the disordered structure of the n-InGaP layer 6 suppresses an induction of traps in the junction of the n-InGaP layer 6 and the n-GaAs layer 7, that is, in the emitter/emitter contact junction.

The reduction of the conduction band discontinuity and the suppression of the trap induction enlarge an effective energy barrier EV1 for a hole in the base layer 4.

The large effective energy barrier EV1 improves the characteristics of the HBT. The offset voltage appearing in the collector current and voltage property is reduced to 100 mV or less. In addition, the current gain becomes 100 or more in a region where a collector current density is very low such as about 100 A/cm². As a result, it is possible to attain the HBT having the superior reliability.

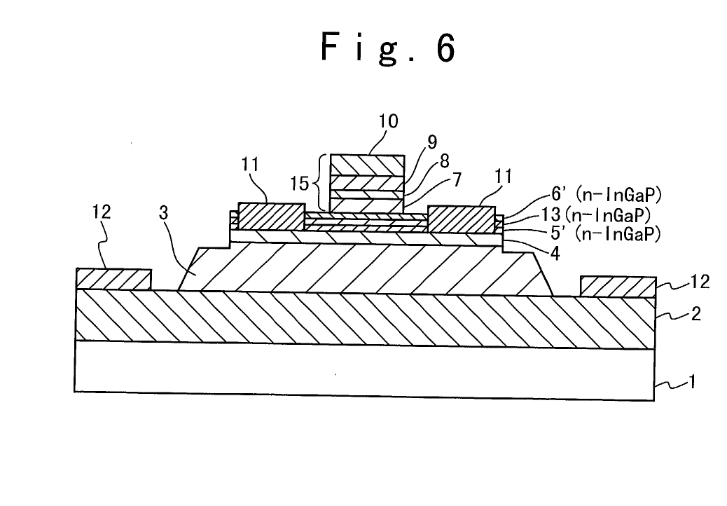

FIG. 6 shows another embodiment of the semiconductor device according to the present invention. An n-InGaP layer 5′ having the ordered structure is formed on the upper surface of the above-mentioned p-GaAs layer 4. The n-InGaP layer 5′ has a film thickness is 15 nm and a carrier concentration is 3×10¹⁷ cm⁻³. An n-InGaP layer 13 having an intermediately ordered structure is formed on an upper surface of the n-InGaP layer 5′. The n-InGaP layer 13 has a film thickness of 15 nm and a dopant concentration of 3×10¹⁷ cm⁻³. An n-InGaP layer 6′ having the disordered structure is formed on an upper surface of the n-InGaP layer 13. The n-InGaP layer 6′ has a film thickness of 15 nm and a dopant concentration of 3×10¹⁷ cm⁻³. The n-InGaP layer 5′, the n-InGaP layer 13, and the n-InGaP layer 6′ constitutes an emitter layer. The other lamination structure is equal to the lamination structure of FIG. 4.

The n-InGaP layer 13 does not have the superlattice structure, but has an intermediate regularity, which means that indium phosphide and gallium phosphide are less irregularly layered in the n-InGaP layer 13 than in the n-InGaP layer 6′. Furthermore, the n-InGaP layer 13 is configured such that the regularity gradually decreases as the distance from the n-InGaP layer 6′ decreases. Thus, the n-InGaP layer 5′ and the n-InGaP layer 6′ are connected and formed continuously and integrally without any generation of the energy barrier in the conduction band and the valence band. This results in the drop in the offset voltage, and the reduction in the base leak current. Hence, it is possible to improve the current gain and the reliability.

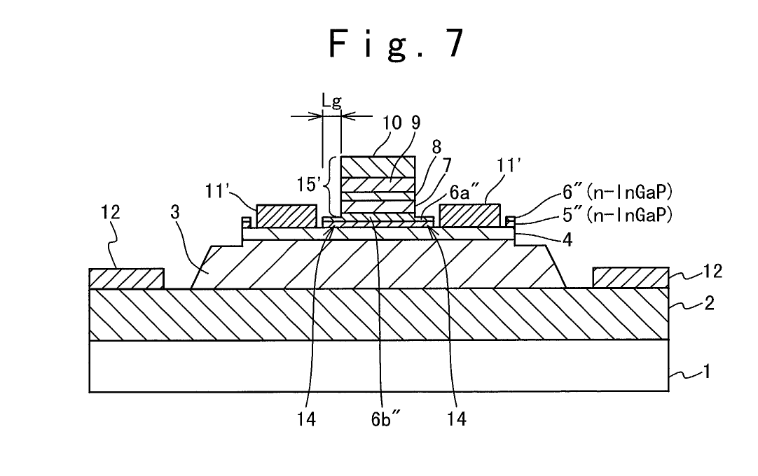

FIG. 7 shows still another embodiment of the semiconductor device according to the present invention. An n-InGaP layer 5″ having the ordered structure is formed on the upper surface of the above-mentioned p-GaAs layer 4. The n-InGaP layer 5″ has a film thickness of 30 nm and a dopant concentration of 3×10¹⁷ cm⁻³. An n-InGaP layer 6″ having the disordered structure is formed on an upper surface of the n-InGaP layer 5″. The n-InGaP layer 6″ has a film thickness of 70 nm and a carrier concentration is 3×10¹⁷ cm ⁻³. The n-InGaP layer 5″ and the n-InGaP layer 6″ constitute an emitter layer.

The n-InGaP layer 6″ includes a first portion 6a″, a second portion 6b″. The first portion 6a″ substantially has a film thickness of 20 nm and a same width as the n-InGaP layer 5″ in the direction parallel to the surface of the GaAs substrate 1.

The second portion 6b″ protrudes from the first portion 6a″ in the direction orthogonal to the surface. The thickness of the second portion 6b″ is 50 nm. The second portion 6b″ is formed by a wet etching of the n-InGaP layer 6″ using the n-GaAs layer 7, the n-GaAs layer 8, the n-InGaAs layer 9 and the emitter electrode 10 as a mask. The second portion 6b″, the n-GaAs layer 7, the n-GaAs layer 8, the n-InGaAs layer 9 and the emitter electrode 10 constitute an emitter mesa 15′.

A base electrode 11′ is formed on the upper surface of the p-GaAs layer 4. A guard ring 14 having a length Lg composed of the n-InGaP layer 5″ and the first portion 6a″ is formed at the tip of the emitter mesa 15′. A film thickness of the guard ring 14 is thin, such as about 50 nm, as a whole. Thus, the guard ring 14 is at a depleted state in a normal operation condition, and thereby enables the reduction in the surface recombination. The length Lg is adjusted to 0.5 μm in this embodiment. Actually, if the length Lg is about 0.2 μm or more, the same effect is obtained. In the present embodiment, the property of the HBT is improved as compared with that of the conventional HBT, similarly to the embodiments shown in FIGS. 4 and 6.

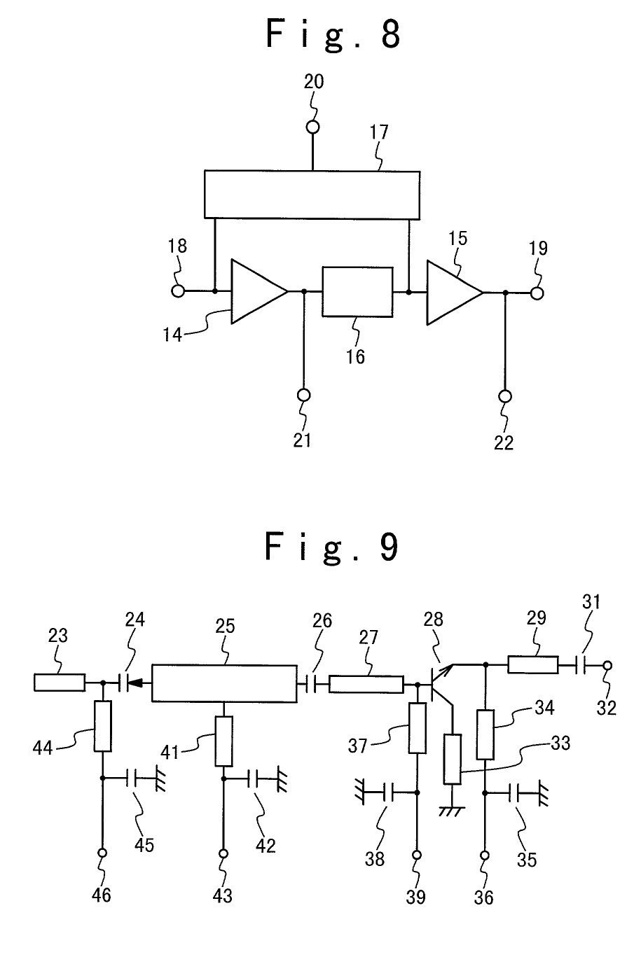

FIG. 8 shows an embodiment of a semiconductor integrated circuit according to the present invention. The semiconductor integrated circuit according to the present invention is preferably applied to a high output amplifier IC for amplifying a signal having a microwave frequency. An input terminal 18, a driver stage HBT 14, a stage-to-stage matching circuit 16, a power stage HBT 15 and an output terminal 19 are connected in turn. A direct current bias supply circuit 17 applies a direct current bias to respective input sides of the driver stage HBT 14 and the power stage HBT 15. A direct current bias supply terminal 21 is connected to an output side of the driver stage HBT 14, and a direct current bias supply terminal 22 is connected to an output side of the power stage HBT 15. Then, a direct current bias is applied through them to the power stage HBT 15. A power supply voltage terminal 20 is connected to the direct current bias supply circuit 17. Each of the driver stage HBT 14 and the power stage HBT 15 is created such that a plurality of semiconductor devices of the embodiment in FIG. 4 are connected in parallel to each other. The total areas of the emitters are 960 μm² and 7200 μm², respectively. Such configuration enables the design of the semiconductor integrated circuit having the excellent property in which a power supply voltage is 3.5 V, an output power is 35 dBm and an additional power efficiency is 60% or more.

FIG. 9 shows an embodiment of a semiconductor integrated circuit according to the present invention. The semiconductor integrated circuit according to the present invention is preferably applied to a voltage control oscillator IC for generating an oscillating signal having an EHF (Extremely High Frequency). Here, the EHF indicates a frequency in the range from 30,000 to 300,000 MHz. A micro strip line 23, a varactor 24, a resonator 25, a capacitor 26, a micro strip line 27, a HBT 28, a micro strip line 29, a capacitor 31 and an output terminal 32 are connected in turn. The semiconductor device of the above-mentioned embodiment in FIG. 6 is used in the HBT 28 serving as an oscillation device. The HBT 28 is used in a collector ground. The HBT 28 is connected to the positive feedback circuit constituted by micro strip lines 33, 34, 37 and capacitors 35, 38. The varactor 24 serving as a modulation device is constituted by a PN junction diode using a base and collector junction. A direct current bias supply circuit composed of a direct current bias supply terminal, the capacitor 26 and a micro strip line having a length of about ¼ wave length are connected to both ends of the varactor 24 and an emitter and a base of the HBT 28. That is, the configuration composed of the micro strip line 34, the capacitor 35 and a direct current bias supply terminal 36 applies a collector bias voltage to the HBT 28. The configuration composed of a micro strip line 37, a capacitor 38 and a direct current bias supply terminal 39 applies a base bias voltage.

A micro strip line 41, a capacitor 42, a direct current bias supply terminal 43, a micro strip line 44, a capacitor 45 and a direct current bias supply terminal 46 apply a direct current bias voltage to the varactor 24. An oscillation frequency is modulated by changing this applied voltage. In this way, a base leak current of the HBT 28 is reduced to thereby improve a 1/f noise property. Thus, it is possible to attain a semiconductor integrated circuit in which a phase noise at a 100 kHz detuning frequency in a 38 GHz band is −90 dBc/Hz and an oscillation output is 8.5 dBm.

In the HBT and the semiconductor integrated circuit according to the present invention, when the InGaP layer is used in the emitter, while the conduction band discontinuity in the boundary between the base and the emitter is kept small, it is possible to reduce the trap in the boundary between the emitter layer and the emitter contact layer and thereby possible to suppress the depletion of the carriers and the recombination. As a result, the offset voltage is low, the current gain is high even in the low current region, and the reliability is excellent.

The semiconductor integrated circuit according to the present invention is excellent in stability, due to the usage of the semiconductor device according to the present invention.

Although the invention has been described in its preferred form with a certain degree of particularity, it is understood that the present disclosure of the preferred form has been changed in the details of construction and the combination and arrangement of parts may be resorted to without departing from the spirit and the scope of the invention as hereinafter claimed.

What is claimed is:

1. A heterojunction bipolar transistor comprising:
a substrate;
a collector layer covering said substrate;
a base layer formed on said collector layer, and doped with a first conductive type dopant;
an emitter layer formed of a mixed crystal of first and second compound semiconductors on said base layer, and doped with a second conductive type dopant,
an emitter contacting semiconductor layer formed on said emitter layer, and doped with said second conductive type dopant, wherein said emitter layer includes:
a superlattice layer connected to said base layer, and
a disordered layer connected to said emitter contacting semiconductor layer, and
wherein said first and second compound semiconductors are layered to form a superlattice in said superlattice layer, and said first and second compound semiconductors are irregularly layered in said disordered layer.

2. The heterojunction bipolar transistor according to claim 1, wherein said first conductive type is a P-type dopant, and said second conductive type dopant is an N-type dopant.

3. The heterojunction bipolar transistor according to claim 1, wherein said first compound semiconductor is indium phosphide, and said second compound semiconductor is gallium phosphide.

4. The heterojunction bipolar transistor according to claim 3, wherein said base layer is formed of gallium arsenide.

5. The heterojunction bipolar transistor according to claim 4, wherein said mixed crystal has a chemical formula of InₓGa₍₁₋ₓ₎P, where 0.47≦x≦0.52.

6. The heterojunction bipolar transistor according to claim 3, wherein said emitter contacting semiconductor layer is formed of gallium arsenide.

7. The heterojunction bipolar transistor according to claim 1, wherein said mixed crystal has a chemical formula of InₓGa₍₁₋ₓ₎P, where 0.47≦x≦0.52.

8. The heterojunction bipolar transistor according to claim 1, wherein a thickness of said emitter layer is 50 nm or less.

9. The heterojunction bipolar transistor according to claim 1, wherein said emitter layer has a first width in a first direction parallel to a surface of said substrate, and said emitter contacting semiconductor layer has a second width in said first direction,
said first width being larger than said second width.

10. The heterojunction bipolar transistor according to claim 9, wherein a thickness of said emitter layer is 50 nm or less.

11. The heterojunction bipolar transistor according to claim 1, wherein said disordered layer comprises:
a first portion connected to said superlattice layer,
a second portion protruding from said first portion in a second direction orthogonal to a surface of said substrate, and
wherein said second portion and said emitter contacting semiconductor layer constitute an emitter mesa, and
wherein said first portion and said superlattice layer have a third width in a first direction parallel to said surface, and said emitter mesa has a fourth width in said first direction, and
wherein said third width is larger than said fourth width.

12. The heterojunction bipolar transistor according to claim 11, wherein a sum of thicknesses of said first portion and said superlattice layer is 50 nm or less.

13. The heterojunction bipolar transistor according to claim 1, wherein said emitter layer further includes an intermediate layer formed between said superlattice layer and said disordered layer, and
wherein said first and second compound semiconductors are less irregularly layered in said intermediate layer than in said disordered layer.

14. An integrated circuit comprising:
a heterojunction bipolar transistor including:
a substrate;
a collector layer covering said substrate;
a base layer formed on said collector layer, and doped with a first conductive type dopant;
an emitter layer formed of a mixed crystal of first and second compound semiconductors on said base layer, and doped with a second conductive type dopant,
an emitter contacting semiconductor layer formed on said emitter layer, and doped with said second conductive type dopant, wherein said emitter layer comprises:
a superlattice layer connected to said base layer, and
a disordered layer connected to said emitter contacting semiconductor layer, and
wherein said first and second compound semiconductors are layered to form a superlattice in said superlattice layer, and said first and second compound semiconductors are irregularly layered in said disordered layer.

15. The integrated circuit according to claim 14, wherein said first compound semiconductor is indium phosphide, and said second compound semiconductor is gallium phosphide.

16. An amplifier amplifying a signal having a microwave frequency, comprising:
a heterojunction bipolar transistor including:
a substrate;
a collector layer covering said substrate;
a base layer formed on said collector layer, and doped with a first conductive type dopant;
an emitter layer formed of a mixed crystal of first and second compound semiconductors on said base layer, and doped with a second conductive type dopant,
an emitter contacting semiconductor layer formed on said emitter layer, and doped with said second conductive type dopant, wherein said emitter layer comprises:
a superlattice layer connected to said base layer, and
a disordered layer connected to said emitter contacting semiconductor layer, and
wherein said first and second compound semiconductors are layered to form a superlattice in said superlattice layer, and said first and second compound semiconductors are irregularly layered in said disordered layer.

17. The amplifier according to claim 16, wherein said first compound semiconductor is indium phosphide, and said second compound semiconductor is gallium phosphide.

18. An oscillator generating a oscillating signal having a EHF (Extremely High Frequency), comprising a heterojunction bipolar transistor, including:
a substrate;
a collector layer covering said substrate;
a base layer formed on said collector layer, and doped with a first conductive type dopant;
an emitter layer formed of a mixed crystal of first and second compound semiconductors on said base layer, and doped with a second conductive type dopant,
an emitter contacting semiconductor layer formed on said emitter layer, and doped with said second conductive type dopant, wherein said emitter layer comprises:
a superlattice layer connected to said base layer, and
a disordered layer connected to said emitter contacting semiconductor layer, and
wherein said first and second compound semiconductors are layered to form a superlattice in said superlattice layer, and said first and second compound semiconductors are irregularly layered in said disordered layer.

19. The oscillator according to claim 18, wherein said first compound semiconductor is indium phosphide, and said second compound semiconductor is gallium phosphide.
